(19) United States
(12) Patent Application Publication
(10) Pub. No.: US 2026/0231683 A1
(43) Pub. Date: Aug. 6, 2026

(54) PIEZOELECTRIC ACTUATOR, LIQUID EJECTION HEAD AND RECORDING DEVICE

(71) Applicant: KYOCERA Corporation, Kyoto (JP)

(72) Inventor: Naoki YOSHIOKA, Kirishima-shi, Kagoshima (JP)

(21) Appl. No.: 19/149,843

(22) PCT Filed: Jan. 17, 2024
(86) PCT No.: PCT/JP2024/001156

§ 371 Date: Jul. 22, 2025

(30) Foreign Application Priority Data
Jan. 23, 2023 (JP) 2023-008336

(51) Int. Cl. H10N 30/87; B41J 2/14; H10N 30/853

(52) U.S. Cl. CPC H10N 30/877; B41J 2/14233; H10N 30/8548; H10N 30/871; H10N 30/872; B41J 2002/14491; B41J 2202/03

(57) ABSTRACT

A piezoelectric actuator includes a piezoelectric element that deforms in response to an applied voltage. The piezoelectric element includes: a piezoelectric ceramic body; and an electrode that applies a voltage to the piezoelectric ceramic body. The electrode includes: a base material containing a noble metal; and a metal oxide, and the metal oxide is dispersed within the base material.

### CROSS-REFERENCE TO RELATED APPLICATIONS

This application is national stage application of International Application No. PCT/JP2024/001156, filed on Jan. 17, 2024, which designates the United States, and which claims the benefit of priority from Japanese Patent Application No. 2023-008336, filed on Jan. 23, 2023.

### DESCRIPTION

### Technical Field

The disclosed embodiments relate to a piezoelectric actuator, a liquid ejection head and a recording device.

### Background of Invention

A known printing device includes an inkjet printer and an inkjet plotter using inkjet recording method. Such an inkjet printing device includes a liquid ejection head for ejecting liquid.

The liquid ejection head ejects the liquid in the pressurizing chamber from the nozzle by driving the piezoelectric element located above the pressurizing chamber to change the pressure in the pressurizing chamber. The piezoelectric element includes a piezoelectric ceramic body and an electrode for applying a voltage to the piezoelectric ceramic body.

In the piezoelectric element, the piezoelectric ceramic body, when subjected to a voltage, is displaced by moving the domain such that the c-axis is oriented in the electric field direction in the piezoelectric ceramic body, thereby generating a driving force.

### CITATION LIST

### Patent Literature

Patent Document 1: JP 2000-094681 A

### SUMMARY

The disclosed piezoelectric actuator includes a piezoelectric element that is deformed upon application of a voltage. The piezoelectric element includes a piezoelectric ceramic body and an electrode that applies a voltage to the piezoelectric ceramic body. The electrode contains a base material containing a noble metal and a metal oxide, and the metal oxide is dispersed within the base material.

### BRIEF DESCRIPTION OF THE DRAWINGS

FIG. 1 is a schematic side view of a printer according to an embodiment.

FIG. 2 is a schematic plan view of a printer according to an embodiment.

FIG. 3 is a schematic exploded perspective view of a liquid ejection head according to an embodiment.

FIG. 4 is an enlarged plan view of a head body according to an embodiment.

FIG. 5 is an enlarged view of a region surrounded by a dashed line illustrated in FIG. 4.

FIG. 6 is a cross-sectional view taken along a line VI-VI of FIG. 4.

FIG. 7 is a view illustrating an SEM image of a cross-sectional state of a surface electrode of Example 1.

FIG. 8 is a view illustrating an SEM image of a cross-sectional state of a surface electrode of Example 3.

FIG. 9 is a view illustrating an SEM image of a cross-sectional state of a surface electrode of Example 5.

FIG. 10 is a view illustrating an SEM image of a cross-sectional state of a surface electrode of Reference Example 2.

FIG. 11 is a view illustrating a relationship between a baking temperature of the surface electrode and an area ratio of metal oxide in the electrode and at the interface, of the surface electrode.

FIG. 12 is a view illustrating a relationship between the baking temperature of the surface electrode and the area ratio of the metal oxide in the electrode to the metal oxide at the interface of the surface electrode.

FIG. 13 is a view illustrating an SEM image of a surface state of a surface electrode of Example 1.

FIG. 14 is a view illustrating an SEM image of a surface state of a surface electrode of Example 3.

FIG. 15 is a view illustrating an SEM image of a surface state of a surface electrode of Example 5.

FIG. 16 is a view illustrating an SEM image of a surface state of a surface electrode of Reference Example 2.

FIG. 17 is a view illustrating a relationship between the baking temperature of the surface electrode and the area ratio of a metal oxide on the surface of the surface electrode.

FIG. 18 is a view illustrating a relationship between the baking temperature of the surface electrode and the coercive field of the piezoelectric element.

FIG. 19 is a view illustrating a transition of the driving degradation between the piezoelectric element of Example 3 and that of Reference Example 1.

### DESCRIPTION OF EMBODIMENTS

Embodiments of a piezoelectric actuator, a liquid ejection head and a recording device disclosed in the present application will be described below. Note that the present disclosure is not limited by the following embodiments.

A known printing device includes an inkjet printer and an inkjet plotter using inkjet recording method. Such an inkjet printing device is equipped with a liquid ejection head for ejecting liquid.

The liquid ejection head ejects the liquid in the pressurizing chamber from the nozzle by driving the piezoelectric element located above the pressurizing chamber to change the pressure in the pressurizing chamber. The piezoelectric element includes a piezoelectric ceramic body and an electrode for applying a voltage to the piezoelectric ceramic body.

In the piezoelectric element, the piezoelectric ceramic body, when subjected to a voltage, is displaced by moving the domain such that the c-axis is oriented in the electric field direction in the piezoelectric ceramic body, thereby generating a driving force.

However, in the above related art, when the driving of the piezoelectric element is continued, a phenomenon that the domain is gradually fixed inside the piezoelectric ceramic body, may occur. As a result, the displacement amount of the piezoelectric element gradually decreases, so that there is a fear that the desired driving amount of the piezoelectric element cannot be obtained.

Thus, achievement of a technology is expected that can solve the above problems and reduce the driving degradation of the piezoelectric element.

### Configuration of Printer

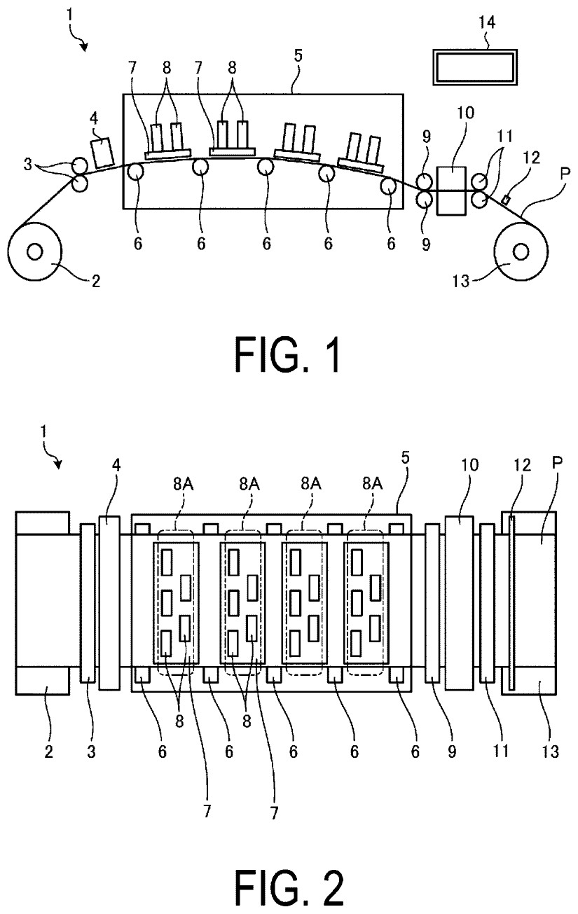

First, with reference to FIGS. 1 and 2, summary of a printer 1, which is an example of a recording device according to an embodiment, will be described. FIG. 1 is a schematic side view of the printer 1 according to an embodiment. FIG. 2 is a schematic plan view of the printer 1 according to an embodiment. The printer 1 according to an embodiment is, for example, a color inkjet printer.

As illustrated in FIG. 1, the printer 1 includes a paper feed roller 2, a pair of guide rollers 3, an applicator 4, a head case 5, a plurality of transport rollers 6, a plurality of frames 7, a plurality of liquid ejection heads 8, a pair of transport rollers 9, a dryer 10, a pair of transport rollers 11, a sensor unit 12, and a collection roller 13.

In addition, the printer 1 includes a controller 14 that controls each part of the printer 1. The controller 14 controls the operation of the paper feed roller 2, the pair of guide rollers 3, the applicator 4, the head case 5, the plurality of transport rollers 6, the plurality of frames 7, the plurality of liquid ejection heads 8, the pair of transport rollers 9, the dryer 10, the pair of transport rollers 11, the sensor unit 12, and the collection roller 13.

The printer 1 records images and characters in the recording medium P by making droplets land on a recording medium P. The recording medium P may be, for example, paper. Without limited to this, the recording medium P may be, for example, cloth. The recording medium P is in a rolled state around the paper feed roller 2 before use. The printer 1 transports the recording medium P rolled around the paper feed roller 2 to the inside of the head case 5 via the pair of guide rollers 3 and the applicator 4.

The applicator 4 uniformly applies coating agent to the recording medium P. This can apply surface treatment to the recording medium P, thereby improving the printing quality of the printer 1.

The head case 5 accommodates the plurality of transport rollers 6, the plurality of frames 7, and a plurality of liquid ejection heads 8. The inside of the head case 5 forms a space isolated from the outside except for a portion connected to the outside such as a portion where the recording medium P enters and leaves.

In the internal space of the head case 5, at least one of the controlling factors such as temperature, humidity, and air pressure is controlled by the controller 14 as required. The transport rollers 6 transport the recording medium P to the vicinity of the liquid ejection heads 8 inside the head case 5.

The frame 7 is a rectangular flat plate and is positioned close to and upward of the recording medium P transported by the transport rollers 6. As illustrated in FIG. 2, the frame 7 is positioned such that the longitudinal direction is orthogonal to the transport direction of the recording medium P. The plurality of (e.g., four) frames 7 are positioned inside the head case 5 at predetermined intervals along the transport direction of the recording medium P.

In the following description, the transport direction of the recording medium P may be referred to as “sub scanning direction”, and the direction orthogonal to the sub scanning direction and parallel to the recording medium P may be referred to as “main scanning direction”.

Liquid, e.g., ink, is supplied to the liquid ejection head 8 from a liquid tank (not illustrated). The liquid ejection head 8 ejects the liquid supplied from the liquid tank.

The controller 14 controls the liquid ejection head 8 based on data such as images and characters, and ejects the liquid toward the recording medium P. The distance between the liquid ejection head 8 and the recording medium P is, for example, about 0.5 to 20 mm.

The liquid ejection head 8 is fixed to the frame 7. The longitudinal direction of the liquid ejection head 8 is positioned orthogonal to the transport direction of the recording medium P.

That is, the printer 1 according to the embodiments is a so-called line printer in which the liquid ejection head 8 is fixed to the inside of the printer 1. The printer 1 according to the embodiments is not limited to a line printer, but may be a so-called serial printer.

The serial printer is a type of printer that alternately performs operations of: recording while moving the liquid ejection head 8 in a direction intersecting the transport direction of the recording medium P (for example, by reciprocating in a direction substantially orthogonal to the transport direction); and transporting the recording medium P.

As illustrated in FIG. 2, a plurality of (e.g., five) liquid ejection heads 8 are fixed to one frame 7. FIG. 2 illustrates an example in which three liquid ejection heads 8 are positioned in front of the transport direction of the recording medium P and two liquid ejection heads 8 are positioned in the rear such that the centers of the liquid ejection heads 8 do not overlap each other in the transport direction of the recording medium P.

A head group 8A is composed of a plurality of liquid ejection heads 8 arranged in one frame 7. The four head groups 8A are arranged along the transport direction of the recording medium P. The same color ink is supplied to each of the liquid ejection heads 8 belonging to the same head group 8A. Thus, the printer 1 can print with four colors of ink using the four head groups 8A.

The colors of ink ejected from the head groups 8A are, for example, magenta (M), yellow (Y), cyan (C), and black (K), respectively. The controller 14 can print a color image on the recording medium P by controlling each head group 8A and ejecting a plurality of colors of ink to the recording medium P.

To perform surface treatment of the recording medium P, the coating agent may be ejected from the liquid ejection head 8 to the recording medium P.

The number of liquid ejection heads 8 included in one head group 8A and the number of head groups 8A mounted on the printer 1 can be appropriately changed depending on the printing object and printing conditions. For example, when the color to be printed on a printing medium P is a single color and one liquid ejection head 8 can print the range to be printed, the number of liquid ejection heads 8 mounted on the printer 1 may be one.

The recording medium P that has been printed inside the head case 5 is transported to the outside of the head case 5 by the pair of transport rollers 9, and passes through the inside of the dryer 10. The dryer 10 dries the recording medium P that has been printing processed. The recording medium P dried in the dryer 10 is transported by the pair of transport rollers 11 and collected by the collection roller 13.

In the printer 1, drying the printing medium P with the dryer 10 can reduce adhesion of the printing medium P wound in an overlapping manner, and rubbing of undried liquid, at the collection roller 13.

The sensor unit 12 is composed of a position sensor, a speed sensor, and a temperature sensor, or the like. The controller 14 determines the state of each part of the printer 1 based on the information from the sensor unit 12, and can control each part of the printer 1.

The printer 1 described, as one case, so far uses the recording medium P as the printing object (i.e., a recording medium). However, the printing object in the printer 1 is not limited to the recording medium P, and a rolled cloth or the like may be used as the printing object.

Instead of directly transporting the recording medium P itself, the printer 1 may transport the object placed on a transport belt. By using the transport belt, the printer 1 can print a sheet of paper, cut cloth, wood, or tile, as a printing object.

In addition, the printer 1 may print wiring patterns of electronic equipment by ejecting liquid that contains conductive particles from the liquid ejection head 8. In addition, the printer 1 may produce chemicals by ejecting a predetermined amount of liquid chemical agents, or liquid that contains chemical agents, from the liquid ejection head 8 toward a reaction vessel, or the like.

### Configuration of Liquid Ejection Head

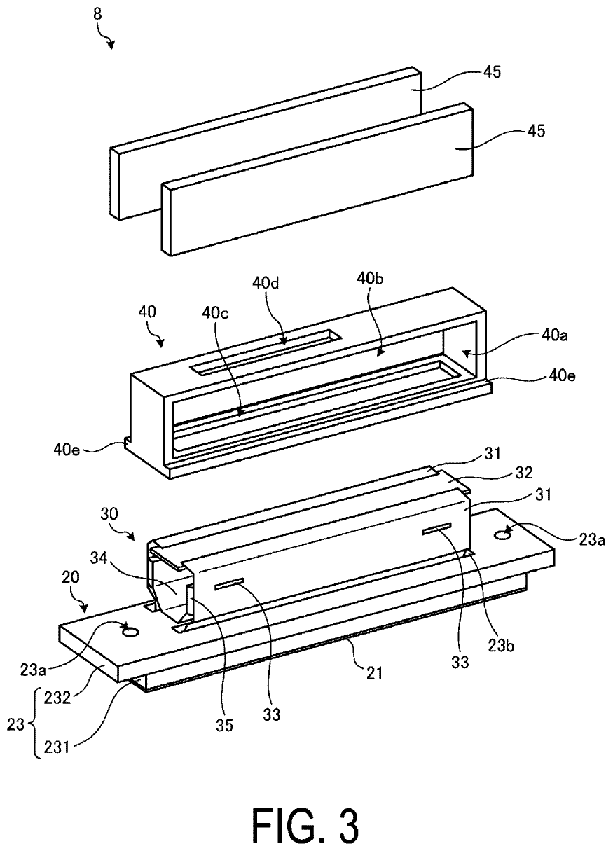

Next, the configuration of the liquid ejection head 8 according to an embodiment will be described with reference to FIG. 3. FIG. 3 is a schematic exploded perspective view of the liquid ejection head 8 according to an embodiment.

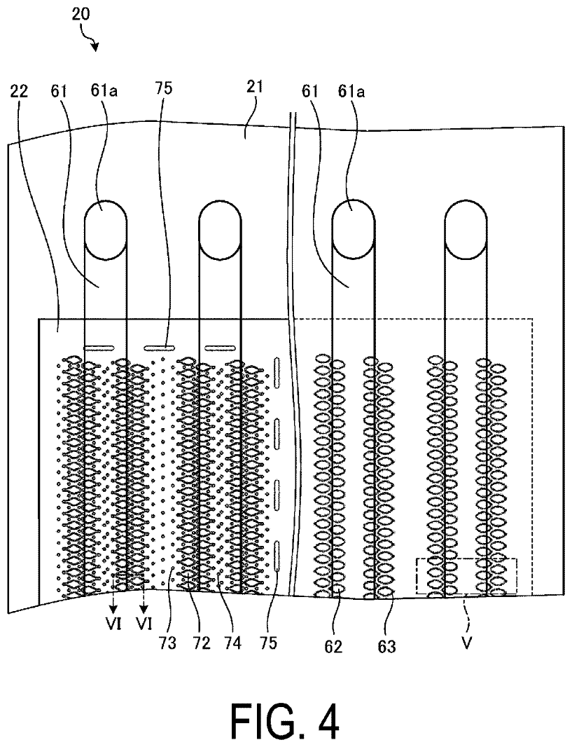

The liquid ejection head 8 includes a head body 20, a wiring portion 30, a casing 40, and a pair of heat dissipation plates 45. The head body 20 includes a channel member 21, a piezoelectric actuator substrate 22 (see FIG. 4), and a reservoir 23.

In the following description, for convenience, a direction in which the head body 20 is provided in the liquid ejection head 8 may be represented as “lower”, and a direction in which the casing 40 is provided with respect to the head body 20 may be represented as “upper”.

The channel member 21 of the head body 20 has a substantially flat plate shape, and includes a first surface 21a (see FIG. 6), which is one main surface, and a second surface 21b (see FIG. 6) located on the opposite side to the first surface 21a. The first surface 21a includes an opening (not illustrated), and a liquid is supplied from the reservoir 23 described below to the inside of the channel member 21 through the opening.

The second surface 21b has a plurality of ejection holes 63 (see FIG. 6) that eject liquid to the recording medium P. That is, the second surface 21b is a nozzle surface of the head body 20. The channel member 21 includes a channel that flows liquid from the first surface 21a to the second surface 21b. The ejection hole 63 is an example of a nozzle.

The piezoelectric actuator substrate 22 is located on the first surface 21a of the channel member 21. The piezoelectric actuator substrate 22 includes a plurality of piezoelectric elements 70 (see FIG. 6). A flexible substrate 31 of a wiring portion 30 is electrically connected to the piezoelectric actuator substrate 22. The configuration of the piezoelectric actuator substrate 22 will be described below with reference to FIGS. 4 to 6.

The reservoir 23 is located on the piezoelectric actuator substrate 22. Specifically, the reservoir 23 is located on the first surface 21a of the channel member 21 so as to cover the piezoelectric actuator substrate 22.

The reservoir 23 supplies liquid to a pressurizing chamber 62 described below of the channel member 21. Specifically, the reservoir 23 is provided with an opening 23a at each end in the longitudinal direction. The reservoir 23 includes a channel inside, and liquid is supplied from the outside through the opening 23a. The reservoir 23 has a function of supplying liquid to the pressurizing chamber 62 of the channel member 21 and a function of storing the supplied liquid.

The wiring portion 30 includes the flexible substrate 31, a head substrate 32, a driver IC 33, a pressing member 34, and an elastic member 35. The flexible substrate 31 has a function of transmitting a predetermined signal sent from the outside to the head body 20. As illustrated in FIG. 3, the liquid ejection head 8 according to the embodiment includes two flexible substrates 31.

One end of the flexible substrate 31 is electrically connected to the piezoelectric actuator substrate 22 of the head body 20. The other end of the flexible substrate 31 is drawn upward so as to pass through an opening 23b of the reservoir 23, and is electrically connected to the head substrate 32.

Thus, the piezoelectric actuator substrate 22 of the head body 20 can be electrically connected to the outside. The flexible substrate 31 is, for example, a film-shaped substrate (COF) made of polyimide, and the driver IC 33 or the like is mounted on the substrate.

The head substrate 32 is located above the head body 20. The head substrate 32 has a function of distributing signals to the driver IC 33. The driver IC 33 is provided on one main surface of the flexible substrate 31. The driver IC 33 drives the piezoelectric actuator substrate 22 of the head body 20 based on a signal sent from the controller 14 (see FIG. 1). This causes the driver IC 33 to drive the liquid ejection head 8.

The pressing member 34 is substantially U-shaped in cross-sectional view, and presses the driver ICs 33 on the flexible substrate 31 toward a heat dissipation plate 45 from the inside. With this configuration, the embodiment enables heat generated when the driver IC 33 drives to be efficiently dissipated to the heat dissipation plate 45 on the outer side.

The elastic member 35 is positioned so as to be in contact with the outer wall of the pressing portion (not illustrated) of the pressing member 34. By providing such the elastic member 35, the possibility can be reduced that the pressing member 34 damages the flexible substrate 31 when the pressing member 34 presses the driver IC 33.

The elastic member 35 is composed of, for example, a foam double-sided tape. In addition, the heat dissipation of the driver IC 33 can be improved by using, for example, a non-silicon heat conductive sheet as the elastic member 35. It is not necessary to provide the elastic member 35.

The casing 40 is positioned on the head body 20 so as to cover the wiring portion 30. This enables the casing 40 to seal the wiring portion 30. The casing 40 is made of, for example, resin or metal.

The casing 40 has a box shape extending long in the main scanning direction, and includes a first opening 40a and a second opening 40b on a pair of side surfaces facing each other along the main scanning direction. The casing 40 includes a third opening 40c on the lower surface and a fourth opening 40d on the upper surface.

In the first opening 40a, one of the heat dissipation plates 45 is positioned to close the first opening 40a, and in the second opening 40b, the other of the heat dissipation plates 45 is positioned to close the second opening 40b.

The heat dissipation plate 45 is provided in a manner to extend in the main scanning direction, and is made of a metal, an alloy, or the like having a high heat dissipation properties. The heat dissipation plate 45 is provided so as to contact the driver IC 33, and dissipates heat generated in the driver IC 33.

A pair of the heat dissipation plates 45 are each fixed to the casing 40 by screws (not illustrated). Thus, the casing 40, to which the heat dissipation plates 45 are fixed, has a box shape in which the first opening 40a and the second opening 40b are closed, and the third opening 40c and the fourth opening 40d are opened.

The third opening 40c is positioned so as to face the reservoir 23. The flexible substrates 31 and the pressing member 34 are inserted into the third opening 40c.

The fourth opening 40d is provided for the insertion of a connector (not illustrated) located on the head substrate 32. When the space between the connector and the fourth opening 40d is sealed with resin or the like, liquid or dust or the like is less likely to enter the casing 40.

The casing 40 includes an insulation portion 40e. The insulation portion 40e is positioned adjacent to the first opening 40a and the second opening 40b, and protrudes outward from the side surface of the casing 40 along the main scanning direction.

The insulation portion 40e is formed so as to extend in the main scanning direction. That is, the insulation portion 40e is positioned between the heat dissipation plate 45 and the head body 20. Thus, by providing the insulation portion 40e in the casing 40, heat generated in the driver IC 33 becomes less likely to be transmitted to the head body 20 through the heat dissipation plate 45.

The configuration of the liquid ejection head 8 illustrated in FIG. 3 is only an example, and is not limited to the configuration illustrated in FIG. 3.

### Configuration of Head Body

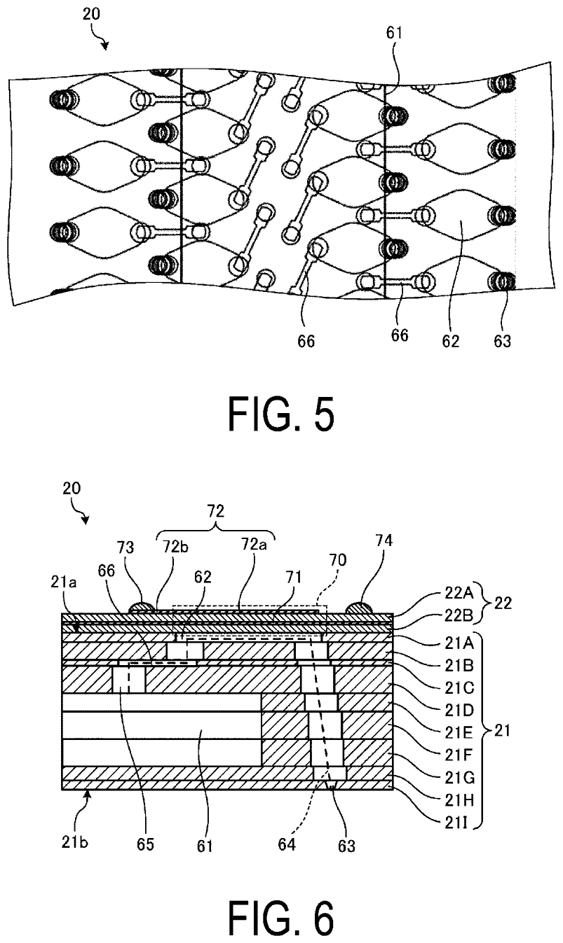

Next, the configuration of the head body 20 according to the embodiment will be described with reference to FIGS. 4 to 6. FIG. 4 is an enlarged plan view of the head body 20 according to the embodiment. FIG. 5 is an enlarged view of a region V surrounded by a dashed line illustrated in FIG. 4. FIG. 6 is a cross-sectional view taken along a line VI-VI illustrated in FIG. 4.

As illustrated in FIG. 4, the head body 20 includes the channel member 21 and the piezoelectric actuator substrate 22. The channel member 21 includes a supply manifold 61, a plurality of pressurizing chambers 62, and the plurality of ejection holes 63.

A plurality of the pressurizing chambers 62 are connected to the supply manifold 61. A plurality of the ejection holes 63 are connected to the plurality of the pressurizing chambers 62, respectively.

The pressurizing chamber 62 is opened to the first surface 21a of the channel member 21 (see FIG. 6). The first surface 21a of the channel member 21 includes an opening 61a connected to the supply manifold 61. Liquid is supplied from the reservoir 23 (see FIG. 2) into the channel member 21 via the opening 61a.

In the example illustrated in FIG. 4, the head body 20 includes four supply manifolds 61 inside the channel member 21. The supply manifold 61 has a long thin shape extending along the longitudinal direction (i.e., the main scanning direction) of the channel member 21. On the first surface 21a of the channel member 21, at both ends of the supply manifold 61, the openings 61a are formed, respectively.

In the channel member 21, a plurality of the pressurizing chambers 62 are formed to extend two-dimensionally. As illustrated in FIG. 5, the pressurizing chamber 62 is, for example, a hollow region having a substantially rhombic planar shape with rounded corners. The shape of the pressurizing chamber 62 is not limited to the example illustrated in the drawing. The pressurizing chamber 62 is opened on the first surface 21a of the channel member 21, and is closed by joining the piezoelectric actuator substrate 22 to the first surface 21a.

The pressurizing chambers 62 constitute a pressurizing chamber row arranged longitudinally. The pressurizing chambers 62 of the pressurizing chamber row are arranged in a staggered pattern between two adjacent pressurizing chamber rows. Four pressurizing chamber rows connected to one supply manifold 61 constitute one pressurizing chamber group. In the example illustrated in FIG. 4, the channel member 21 includes four pressurizing chamber groups.

In addition, the pressurizing chambers 62 in each pressurizing chamber group has the same relative arrangement, and arrangement of the pressurizing chamber group is slightly displaced in the longitudinal direction from each other.

The ejection hole 63 is positioned in the channel member 21 at a location that avoids the region facing the supply manifold 61. That is, when the channel member 21 is viewed in a transmissive manner from the first surface 21a side, the ejection hole 63 does not overlap the supply manifold 61.

Furthermore, when viewed in plan view, the ejection holes 63 are positioned so as to fit in the mounting region of the piezoelectric actuator substrate 22. Such ejection holes 63 occupy, as a group, a region of substantially the same size and shape as the piezoelectric actuator substrate 22.

In the liquid ejection head 8, the driver IC 33 displaces the piezoelectric elements 70 (see FIG. 6) of the piezoelectric actuator substrate 22 based on signals sent from the controller 14 (see FIG. 1). This ejects the liquid in the pressurizing chamber 62 from the ejection hole 63 by pressing the pressurizing chamber 62.

As illustrated in FIG. 6, the channel member 21 has a laminated structure in which a plurality of plates are stacked. For example, the channel member 21 includes a cavity plate 21A, a base plate 21B, an aperture plate 21C, a supply plate 21D, manifold plates 21E, 21F, 21G, a cover plate 21H, and a nozzle plate 21I in order from the upper surface of the channel member 21.

Many holes are formed in those plates. The thickness of the plate is about 10 μm to 300 μm. This allows the accuracy of hole formation to increase. The plates are laminated in alignment such that the holes communicate with each other to form a predetermined flow path.

In the channel member 21, the supply manifold 61 and the ejection hole 63 are connected by an individual channel 64. The supply manifold 61 is positioned on the side of the second surface 21b inside the channel member 21, and the ejection hole 63 is positioned on the second surface 21b of the channel member 21.

The individual channel 64 includes the pressurizing chamber 62 and an individual supply channel 65. The pressurizing chamber 62 is positioned on the first surface 21a of the channel member 21, and the individual supply channel 65 is a channel connecting the supply manifold 61 and the pressurizing chamber 62.

In addition, the individual supply channel 65 includes a throttle 66 that is narrower than the other parts. The throttle 66 is narrower than the other parts of the individual supply channel 65, so that the channel resistance is high. Thus, when the channel resistance of the throttle 66 is high, the pressure generated in the pressurizing chamber 62 is difficult to escape to the supply manifold 61.

The piezoelectric actuator substrate 22 include piezoelectric ceramic layers 22A, 22B, an internal electrode 71, a surface electrode 72, a connecting electrode 73, a dummy connecting electrode 74, and a surface electrode 75 (see FIG. 4). The piezoelectric ceramic layer 22A is an example of a piezoelectric ceramic body, and the surface electrode 72 is an example of an electrode.

The piezoelectric ceramic layer 22B, the internal electrode 71, the piezoelectric ceramic layer 22A, and the surface electrode 72 are laminated in this order from the bottom, that is, from the channel member 21 side.

The piezoelectric ceramic layers 22A and 22B extend on the first surface 21a of the channel member 21 so as to straddle a plurality of the pressurizing chambers 62. Each of the piezoelectric ceramic layers 22A and 22B has a thickness of about 20 μm. The piezoelectric ceramic layers 22A and 22B are each composed of, for example, a ferroelectric lead zirconate titanate (PZT) based ceramic material.

The internal electrode 71 is formed in the region between the piezoelectric ceramic layer 22A and the piezoelectric ceramic layer 22B over the entire surface in the plane direction. That is, the internal electrode 71 overlaps all the pressurizing chambers 62 in the region facing the piezoelectric actuator substrate 22.

The thickness of the internal electrode 71 is about 2 μm. The internal electrode 71 is composed of a metal material such as, for example, an Ag—Pd based material.

The surface electrode 72 includes a body electrode 72a and a lead electrode 72b. The body electrode 72a is positioned in the region, above the piezoelectric ceramic layer 22A and facing the pressurizing chamber 62. The body electrode 72a is one size smaller than the pressurizing chamber 62 and has a shape substantially similar to that of the pressurizing chamber 62.

The lead electrode 72b is drawn out from the body electrode 72a to the outside of the region facing the pressurizing chamber 62. The surface electrode 72 is composed of a noble metal material such as Au or Ag as a base material. Details of the surface electrode 72 will be described below.

The connecting electrode 73 is located on the lead electrode 72b and has a thickness of about 15 μm and is formed in a convex shape. The connecting electrode 73 is electrically connected to an electrode provided on the flexible substrate 31 (see FIG. 3). The connecting electrode 73 is made of, for example, silver-palladium containing glass frit.

The dummy connecting electrode 74 is positioned on the piezoelectric ceramic layer 22A so as not to overlap various electrodes such as the surface electrode 72. The dummy connecting electrode 74 connects the piezoelectric actuator substrate 22 and the flexible substrate 31 to enhance the connection strength.

In addition, the dummy connecting electrode 74 equalizes the distribution of the contact positions between the piezoelectric actuator substrate 22 and the flexible substrate 31, thereby stabilizing the electrical connection. The dummy connecting electrode 74 may be made of the same material as the connecting electrode 73 and formed by the same process as the connecting electrode 73.

The surface electrode 75 illustrated in FIG. 4 is formed on the piezoelectric ceramic layer 22A to avoid the surface electrode 72. The surface electrode 75 is connected to the internal electrode 71 through a via hole formed in the piezoelectric ceramic layer 22A.

Thus, the surface electrode 75 is grounded and held at the ground potential. The surface electrode 75 may be made of the same material as the surface electrode 72, and may be formed by the same process as the surface electrode 72.

To individually control the potential, the plurality of surface electrodes 72 are electrically and individually connected to the controller 14 (see FIG. 1) through the flexible substrate 31 and the wiring. The surface electrode 72 and the internal electrode 71 are set to different potentials and an electric field is applied in the polarization direction of the piezoelectric ceramic layer 22A. Then, the portion of the piezoelectric ceramic layer 22A to which the electric field is applied, acts as an active portion distorted by the piezoelectric effect.

That is, in the piezoelectric actuator substrate 22, the portion that is constituted by the surface electrode 72, the piezoelectric ceramic layer 22A, and the internal electrode 71, and that face the pressurizing chamber 62, functions as the piezoelectric element 70.

Then, by unimorph deformation of such piezoelectric element 70, the pressurizing chamber 62 is pressed, and the liquid droplets are ejected from the ejection hole 63.

Here, the driving procedure of the liquid ejection head 8 according to the embodiment will be described. In advance, the surface electrode 72 is set to a higher potential (hereinafter referred to as high potential) than the internal electrode 71. Each time an ejection request is made, the surface electrode 72 is set to the same potential (hereinafter referred to as low potential) as the internal electrode 71, and then set to a higher potential again at a predetermined timing.

As a result, at the timing when the surface electrode 72 becomes low, the piezoelectric ceramic layers 22A and 22B each return to the original shape, and the volume of the pressurizing chamber 62 increases from the initial state, that is, the high potential state. At this time, a negative pressure is applied to the pressurizing chamber 62, so that the liquid in the supply manifold 61 is sucked into the pressurizing chamber 62.

Then, at the timing when the surface electrode 72 is set to a higher potential again, the piezoelectric ceramic layers 22A and 22B are deformed so as to become convex toward the pressurizing chamber 62. That is, the pressure in the pressurizing chamber 62 becomes positive pressure because the volume of the pressurizing chamber 62 decreases. As a result, the pressure of the liquid in the pressurizing chamber 62 rises, and liquid droplets are ejected from the ejection hole 63.

That is, in order to eject liquid droplets from the ejection hole 63, the controller 14 uses the driver IC 33 to supply a driving signal including a pulse with a high potential as a reference to the surface electrode 72. The pulse width may be AL (Acoustic Length), which is the time length for the pressure wave to propagate from the throttle 66 to the ejection hole 63.

This allows the pressure in the pressurizing chamber 62 to transition from a negative to a positive state, during which the both pressure components combine to eject the droplets with a greater pressure.

In the gradation printing, the gradation expression is performed by the number of droplets continuously ejected from the ejection hole 63, that is, the amount of droplets (volume) adjusted by the number of times of liquid ejection. Thus, the number of times of liquid ejection corresponding to the specified gradation expression is continuously performed from each of the ejection holes 63 corresponding to the specified dot region.

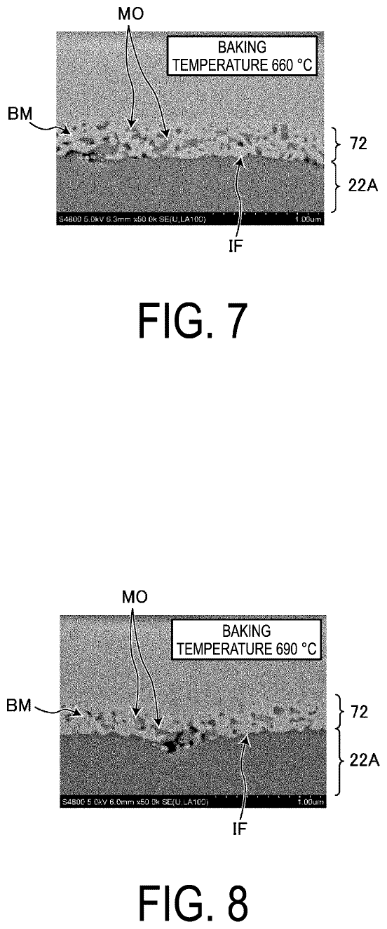

Here, in the embodiment, the surface electrode 72 of the piezoelectric element 70 may contain a base material BM (see FIG. 7) containing a noble metal and a metal oxide MO (see FIG. 7). In the embodiment, the metal oxide MO may be dispersed within the base material BM.

As a result, the hardness of the surface electrode 72 is increased, so that when the piezoelectric element 70 is driven, excessive distortion is less likely to occur in the inactive portion adjacent to the active portion of the piezoelectric ceramic layer 22A.

Thus, the fixation of the domain caused by excessive distortion is reduced in the inactive portion adjacent to the active portion of the piezoelectric ceramic layer 22A. Thus, according to the embodiment, since the coercive field of the piezoelectric element 70 is increased, the driving degradation of the piezoelectric element 70 is reduced.

In the embodiment, the area ratio of the metal oxide MO dispersed within the base material BM may be in the range of 15% to 30%, and preferably in the range of 20% to 30%. In other words, in the SEM cross section of the surface electrode 72, a metal oxide MO not in contact with an interface IF has an area ratio in the range of 15% to 30%, more preferably in the range of 20% to 30%, relative to the base material BM.

By having the area ratio of the metal oxide MO in the above range, the fixation of the domain caused by excessive distortion in the inactive portion adjacent to the active portion of the piezoelectric ceramic layer 22A is further reduced. Thus, according to the embodiment, the coercive field of the piezoelectric element 70 is further increased, and thus the driving degradation of the piezoelectric element 70 is further reduced.

In the embodiment, the metal oxide MO may be positioned at the interface IF (see FIG. 7) between the base material BM and the piezoelectric ceramic layer 22A. This improves the adhesion between the surface electrode 72 and the piezoelectric ceramic layer 22A, thereby improving the reliability of the liquid ejection head 8.

In the embodiment, the area ratio of the metal oxide MO dispersed within the base material BM to the metal oxide MO located at the interface IF between the base material BM and the piezoelectric ceramic layer 22A may be in the range of 20% to 60%, and preferably in the range of 40% to 60%. In other words, in the SEM cross section of the surface electrode 72, the area ratio of the metal oxide MO in contact with the interface IF is in the range of 20 to 60%, more preferably in the range of 40% to 60%, relative to the base material BM.

By having the area ratio of the metal oxide MO in the above range, the fixation of the domain caused by excessive distortion in the inactive portion adjacent to the active portion of the piezoelectric ceramic layer 22A is further reduced. Thus, according to the embodiment, the coercive field of the piezoelectric element 70 is further increased, so that the driving degradation of the piezoelectric element 70 is further reduced.

In the embodiment, the metal oxide MO may be exposed on the surface of the base material BM in the surface electrode 72 of the piezoelectric element 70.

As a result, the hardness of the surface electrode 72 is increased, so that when the piezoelectric element 70 is driven, excessive distortion is less likely to occur in the inactive portion adjacent to the active portion of the piezoelectric ceramic layer 22A.

Thus, the fixation of the domain caused by excessive distortion is reduced in the inactive portion adjacent to the active portion of the piezoelectric ceramic layer 22A. Thus, according to the embodiment, the coercive field of the piezoelectric element 70 is increased, so that the driving degradation of the piezoelectric element 70 is reduced.

In the embodiment, the area ratio of the metal oxide MO exposed on the surface of the base material BM may be in the range of 0.5% to 6%, and preferably in the range of 2% to 6%. In other words, the area ratio of the metal oxide MO exposed from the base material BM in the SEM surface photograph of the surface electrode 72 is in the range of 0.5% to 6%, more preferably in the range of 2% to 6%, relative to the base material BM.

By having the area ratio of the metal oxide MO in the above range, the fixation of the domain caused by excessive distortion in the inactive portion adjacent to the active portion of the piezoelectric ceramic layer 22A is further reduced. Thus, according to the embodiment, the coercive field of the piezoelectric element 70 is further increased, so that the driving degradation of the piezoelectric element 70 is further reduced.

In the embodiment, the metal oxide MO may include a metal oxide contained in the piezoelectric ceramic layer 22A. For example, when the piezoelectric ceramic layer 22A is composed of PZT, the metal oxide MO may include at least one of lead (Pb), zirconium (Zr) and titanium (Ti) oxides contained in the PZT.

This improves the adhesion between the surface electrode 72 and the piezoelectric ceramic layer 22A, thereby improving the reliability of the liquid ejection head 8.

In the embodiment, the metal oxide MO may contain Pb oxide. This can reduce excessive hardening, which is caused by addition of the metal oxide MO, of the surface electrode 72 composed of the base material BM of a noble metal. Thus, according to the embodiment, the inhibition of the unimorph deformation of the piezoelectric element 70 due to excessive hardening of the surface electrode 72, can be reduced.

Furthermore, in the embodiment, the inclusion of metal oxide MO with Pb oxide improves the adhesion between the surface electrode 72 and the piezoelectric ceramic layer 22A, thereby enhancing the reliability of the liquid ejection head 8.

Furthermore, in the embodiment, the base material BM may be composed mainly of a noble metal such as, for example, Au or Ag. As a result, the surface electrode 72 can be prevented from becoming excessively hard, thereby reduces hindrance to the unimorph deformation of the piezoelectric element 70.

In the embodiment, the piezoelectric element 70 may include an electrode that has the base material BM containing a noble metal, and a metal oxide MO, and the metal oxide MO is dispersed within the base material BM. This electrode may be the surface electrode 72. This increases the coercive field of the piezoelectric element 70, thereby reducing the driving degradation of the piezoelectric element 70.

In the piezoelectric element 70, the electrode including a base material BM containing a noble metal and a metal oxide MO, and the metal oxide MO dispersed within the base material BM, may not be limited to the surface electrode 72, but may be the internal electrode 71. This also increases the coercive field of the piezoelectric element 70, thereby reducing the driving degradation of the piezoelectric element 70.

### EXAMPLES

Examples of the present disclosure will be specifically described below. In the examples described below, PZT is used as the piezoelectric ceramic layer 22A, Au is used as the base material BM of the surface electrode 72, and Pb oxide is used as the metal oxide MO, but the present disclosure is not limited to the following examples.

### Example 1

First, a laminate body composed of the channel member 21 (see FIG. 6) and the piezoelectric actuator substrate 22 (see FIG. 6) was prepared. Next, a paste containing Au and Pb oxides was applied to the surface of the piezoelectric ceramic layer 22A in the piezoelectric actuator substrate 22 by screen printing. This paste was applied in a position and shape corresponding to the surface electrode 72 (see FIG. 6).

Next, the laminate body on which the paste containing Au and Pb oxides was applied, was subjected to a baking treatment. This baking treatment was performed at a maximum temperature (hereinafter also called baking temperature) of 660° C. in the atmosphere. Thus, the paste containing Au and Pb oxides was baked, and the surface electrode 72 was formed on the surface of the piezoelectric ceramic layer 22A.

Next, the head body 20 (see FIG. 6) was formed by providing the connecting electrode 73 (see FIG. 6) or the like on the surface electrode 72, and each member illustrated in FIG. 3 was attached to the formed head body 20 to obtain the liquid ejection head 8 (see FIG. 3) of Example 1.

### Examples 2 to 5

The liquid ejection heads 8 of Examples 2 to 5 were obtained using the same method as in Example 1, respectively. In Examples 2 to 5, the pastes containing Au and Pb oxides were baked at baking temperatures of 675° C., 690° C., 705° C., and 720° C. in the atmosphere, respectively.

### Reference Examples 1 and 2

The liquid ejection head 8 of Reference Examples 1 and 2 were obtained using the same method as in Example 1. In Reference Examples 1 and 2, the pastes containing Au and Pb oxides were baked at baking temperatures of 750° C. and 780° C. in the atmosphere, respectively.

### Various Evaluations

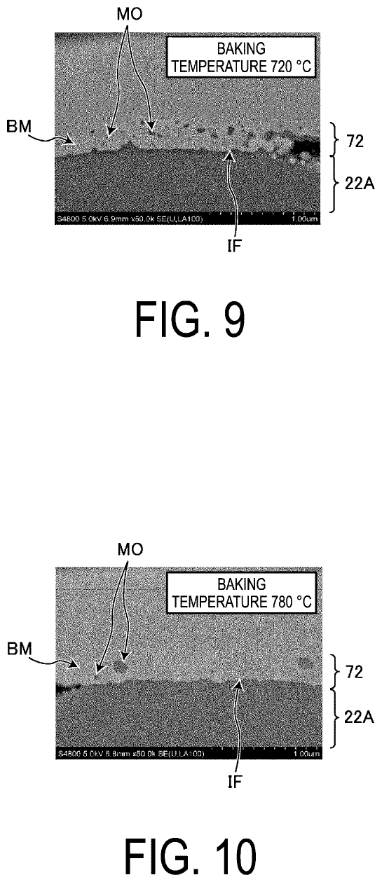

Next, various evaluations were performed on the liquid ejection heads 8 of Examples 1 to 5 and Reference Examples 1 and 2 obtained above, respectively. First, the cross-sectional states of the surface electrodes 72 of Examples 1 to 5 and Reference Examples 1 and 2 were observed by SEM (Scanning Electron Microscope), respectively. The observation results are illustrated in FIGS. 7 to 10.

FIGS. 7 to 10 illustrate SEM images of the cross-sectional states of the surface electrodes 72 of Example 1, Example 3, Example 5, and Reference Example 2, respectively.

As illustrated in FIGS. 7 to 9, in each of the surface electrodes 72 of Examples 1, 3, and 5, the metal oxide MO composed of Pb oxide was dispersed within the base material BM composed of Au. Although not illustrated, in each of the surface electrodes 72 of Examples 2 and 4, the metal oxide MO composed of Pb oxide was dispersed within the base material BM composed of Au.

On the other hand, as illustrated in FIG. 10, in the surface electrode 72 of Reference Example 2, the metal oxide MO composed of Pb oxide was not dispersed within the base material BM composed of Au, but was located locally. Although not illustrated, in the surface electrode 72 of Reference Example 1, the metal oxide MO composed of Pb oxide was not dispersed within the base material BM composed of Au, but was located locally.

As illustrated in FIGS. 7 to 10, the metal oxide MO was also located at the interface IF between the base material BM and the piezoelectric ceramic layer 22A in the surface electrode 72 of each of Examples 1 to 5 and Reference Examples 1 and 2. The black spot in FIGS. 7 to 10 is not the metal oxide MO but a void.

Next, the area ratio of the metal oxide MO in the electrode per unit area and the area ratio of the metal oxide MO at the interface IF per unit area were determined from the respective SEM images of the cross-sectional states of the surface electrodes 72 of the Examples and Reference Examples described so far.

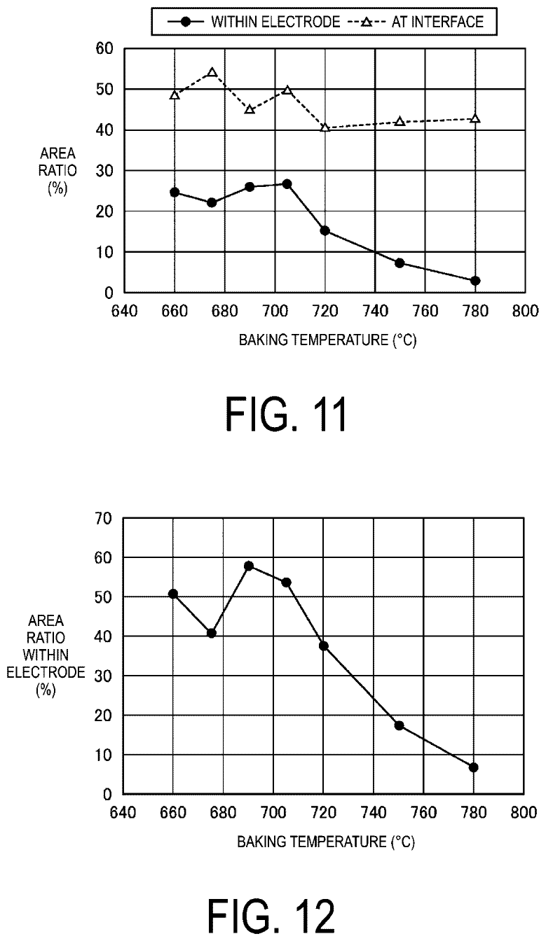

FIG. 11 illustrates the relationship between the baking temperature of the surface electrode 72 and the area ratio of the metal oxide MO in the electrode of the surface electrode 72 and at the interface IF. The metal oxide MO is dispersed within the base material BM in each of the Examples (baking temperature 720° C. or less), so that the area ratio of the metal oxide MO in the electrode was higher than that in each of the Reference Examples (baking temperature 750° C. or more) as illustrated in FIG. 11.

In each Example, the area ratio of metal oxide MO in the electrode was within the range of 15% to 30%. In Examples 1 to 4 (baking temperature 660° C. to 705° C.), the area ratio of the metal oxide MO in the electrode was within the range of 20% to 30%.

Note that, as illustrated in FIG. 11, the area ratio of the metal oxide MO at the interface IF did not significantly change in Examples 1 to 5 and Reference Examples 1 and 2.

FIG. 12 illustrates a relationship between the baking temperature of the surface electrode 72 and the area ratio of the metal oxide MO in the electrode to the metal oxide MO at the interface IF of the surface electrode 72. In each Example (baking temperature 720° C. or less), the metal oxide MO was dispersed within the base material BM, and thus the ratio of the metal oxide MO within the electrode to the metal oxide MO at the interface IF was higher than in Reference Examples 1 and 2 (baking temperature 750° C. or more), as illustrated in FIG. 12.

In each Example, the area ratio of the metal oxide MO in the electrode to the metal oxide MO at the interface IF was within the range of 20% to 60%. In Examples 1 to 4 (baking temperatures of 660° C. to 705° C.), the area ratio of the metal oxide MO in the electrode to that at the interface IF was within a range of 40% to 60%.

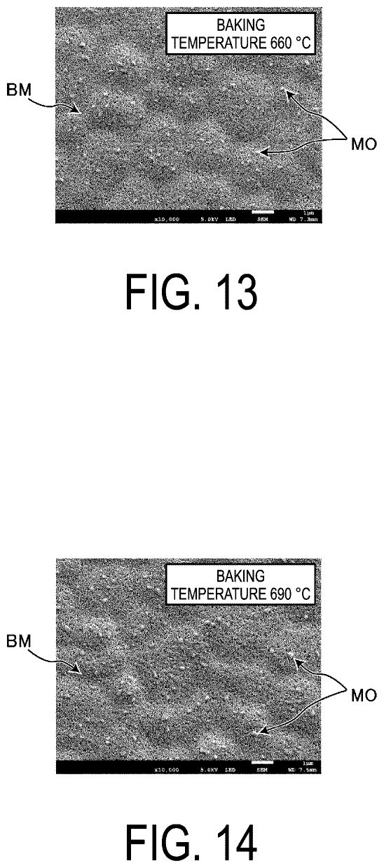

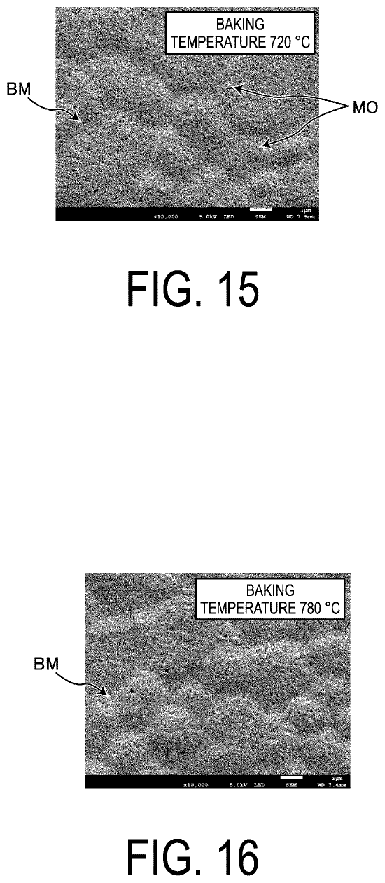

Next, the surface states of the surface electrodes 72 in Examples 1 to 5 and Reference Examples 1 and 2 were observed by SEM, respectively. The observation results are illustrated in FIGS. 13 to 16. FIGS. 13 to 16 illustrate SEM images of the surface states of the surface electrodes 72 in Example 1, Example 3, Example 5, and Reference Example 2, respectively.

As illustrated in FIGS. 13 to 15, in each of the surface electrodes 72 in Examples 1, 3, and 5, granular metal oxide MO composed of Pb oxide was exposed on each surface of the base material BM composed of Au. Although not illustrated, similarly in each of the surface electrodes 72 in Examples 2 and 4, granular metal oxide MO composed of Pb oxide was exposed on each surface of the base material BM composed of Au.

On the other hand, as illustrated in FIG. 16, in the surface electrode 72 in Reference Example 2, the metal oxide MO composed of Pb oxide was not exposed on the surface of the base material BM composed of Au. Although not illustrated, similarly in the surface electrode 72 in Reference Example 1, the metal oxide MO composed of Pb oxide was not exposed on the surface of the base material BM composed of Au.

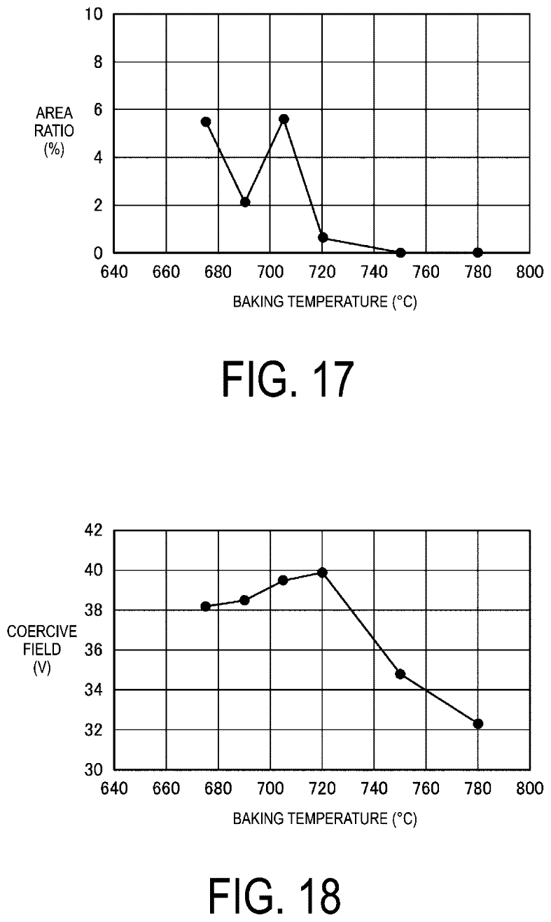

Next, the area ratio of the metal oxide MO on the electrode surface per unit area was obtained from the SEM image of the surface conditions on the surface electrode 72 of each embodiment and each Reference Example described so far. FIG. 17 illustrates a relationship between the baking temperature of the surface electrode 72 and the area ratio of the metal oxide MO on the surface of the surface electrode 72.

As illustrated in FIG. 17, in each embodiment, the area ratio of the metal oxide MO on the surface was within a range of 0.5% to 6%. In Examples 2 to 4 (baking temperature 675° C. to 705° C.), the area ratio of metal oxide MO on the surface was within a range of 2% to 6%. On the other hand, in Reference Examples 1 and 2 (baking temperature 750° C. or higher), the area ratio of the metal oxide MO on the surface was 0 because the metal oxide MO was not exposed on the surface of the base material BM.

Next, the coercive field of the piezoelectric element 70 of each embodiment and each Reference Example was evaluated. Specifically, the hysteresis curve of the piezoelectric element 70 was measured by applying a voltage in the range of −100V to 100V by using a device using a flying probe method. Then, the coercive field of the piezoelectric element 70 was calculated from the value at the point where the hysteresis curve intersects the x-axis (that is, y=0) in the measured hysteresis curve.

FIG. 18 is a diagram illustrating a relationship between the baking temperature of the surface electrode 72 and the coercive field of the piezoelectric element 70. As illustrated in FIG. 18, the coercive field of the piezoelectric element 70 was higher in each embodiment (baking temperature 720° C. or lower) than in each reference example (baking temperature 750° C. or higher).

From the observation results of the cross-sectional SEM images (see FIGS. 7 to 10) and the result of FIG. 18, in the embodiment, the coercive field of the piezoelectric element 70 is recognized to be higher considering that the metal oxide MO is dispersed within the base material BM.

This is presumed to be because the hardness of the surface electrode 72 increases due to the dispersion of the metal oxide MO within the base material BM, which causes excessive strain to be less likely to occur in the inactive portion adjacent to the active portion of the piezoelectric ceramic layer 22A when the piezoelectric element 70 is driven, thereby reducing domain fixation in the inactive portion.

From the results of FIGS. 11 and 18, in the embodiments, the coercive field value of the piezoelectric element 70 is recognized to be higher when the area ratio of the metal oxide MO in the electrode is set to be in the range of 15% to 30%.

Furthermore, from the results of FIGS. 11 and 18, the coercive field value of the piezoelectric element 70 is recognized to be still higher when the area ratio of the metal oxide MO in the electrode is set to be in the range of 20% to 30%.

Additionally, from the results of FIGS. 12 and 18, in the embodiments, the coercive field value of the piezoelectric element 70 is recognized to be higher when the area ratio of the metal oxide MO in the electrode to the metal oxide MO at the interface IF is set to be in the range of 20% to 60%.

Furthermore, from the results of FIGS. 12 and 18, in the embodiments, the coercive field value of the piezoelectric element 70 is recognized to be still higher when the area ratio of the metal oxide MO in the electrode to the metal oxide MO at the interface IF is set to be in the range of 40% to 60%.

Additionally, from the results of FIGS. 17 and 18, in the embodiments, the coercive field value of the piezoelectric element 70 is recognized to be higher when the area ratio of the metal oxide MO in the surface is set to be in the range of 0.5% to 6%.

Furthermore, from the results of FIGS. 17 and 18, in the embodiments, the coercive field value of the piezoelectric element 70 is recognized to be still higher when the area ratio of the metal oxide MO in the surface is set to be in the range of 2% to 6%.

Next, the transition of the driving degradation of each of the piezoelectric element 70 of Example 3 and Reference Example 1 was evaluated. Specifically, for the liquid ejection head 8 of each of Example 3 and Reference Example 1, after the initial ejection amount was measured, a pulse waveform of a predetermined frequency was added to the piezoelectric element 70 to cause the driving degradation, and the ejection amount was measured again after the predetermined cycles of driving.

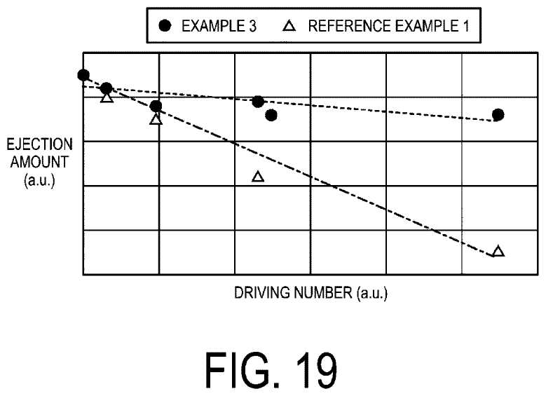

FIG. 19 is a diagram illustrating the transition of the driving degradation of the piezoelectric element 70 of Example 3 and the piezoelectric element 70 of Reference Example 1. From the comparison between the piezoelectric element 70 of Example 3 and the piezoelectric element 70 of Reference Example 1, the driving degradation of the piezoelectric element 70 is recognized to be reduced by increasing the coercive field value of the piezoelectric element 70.

The embodiments of the present disclosure, although has been described above, is not limited to the above embodiment, and various changes can be made without departing from the spirit.

Further effects and other aspects can be easily derived by those skilled in the art. Thus, the broader aspects of the present disclosure are not limited to the specific details and representative embodiments expressed and described above. Accordingly, various modifications are possible without departing from the spirit or scope of the general inventive concept defined by the appended claims and equivalents thereof.

Note that the present technology can also have the following configurations.

(1)
A piezoelectric actuator, including:
a piezoelectric element configured to deform in response to an applied voltage,
wherein
the piezoelectric element includes:
a piezoelectric ceramic body; and
an electrode configured to apply a voltage to the piezoelectric ceramic body,
wherein
the electrode includes:
a base material containing a noble metal; and
a metal oxide, wherein the metal oxide is dispersed within the base material.
   (2)
   The piezoelectric actuator according to above (1), wherein
the area ratio of the metal oxide dispersed within the base material is in the range of 15% to 30%.
   (3)
   The piezoelectric actuator according to above (1), wherein
the area ratio of the metal oxide dispersed within the base material is in the range of 20% to 30%.
   (4)
   The piezoelectric actuator according to any one of above (1) to (3), wherein
the metal oxide is located at an interface between the base material and the piezoelectric ceramic body.
   (5)
   The piezoelectric actuator according to above (4), wherein
the area ratio of the metal oxide dispersed within the base material to the metal oxide located at the interface between the base material and the piezoelectric ceramic body is in the range of 20% to 60%.
   (6)
   The piezoelectric actuator according to above (4), wherein
the area ratio of the metal oxide dispersed within the base material to the metal oxide located at the interface between the base material and the piezoelectric ceramic body is in the range of 40% to 60%.
   (7)
   A piezoelectric actuator, including:
a piezoelectric element that deforms upon application of a voltage,
wherein
the piezoelectric element includes:
a piezoelectric ceramic body; and
an electrode configured to apply a voltage to the piezoelectric ceramic body,
wherein
the electrode includes:
a base material containing a noble metal; and
a metal oxide, wherein the metal oxide is exposed on the surface of the base material.
   (8)
   The piezoelectric actuator according to above (7), wherein
the area ratio of the metal oxide exposed on the surface of the base material is in the range of 0.5% to 6%.
   (9)
   The piezoelectric actuator according to above (7), wherein
the area ratio of the metal oxide exposed on the surface of the base material is in the range of 2% to 6%.
   (10)
   The piezoelectric actuator according to any one of above (1) to (9), wherein
the metal oxide includes an oxide of a metal that is contained in the piezoelectric ceramic body.
   (11)
   The piezoelectric actuator according to any one of above (1) to (9), wherein
the metal oxide includes a Pb oxide.
   (12)
   The piezoelectric actuator according to any one of above (1) to (11), wherein
the electrode is a surface electrode located on the surface of the piezoelectric ceramic body.
   (13)
   A liquid ejection head, including:
a nozzle configured to eject liquid droplets;
a pressurizing chamber connected to the nozzle; and
a piezoelectric element configured to deform in response to an applied voltage, thereby
deforming the pressurizing chamber,
wherein
the piezoelectric element includes:
a piezoelectric ceramic body; and
an electrode configured to apply a voltage to the piezoelectric ceramic body,
wherein
the electrode includes:
a base material containing a noble metal; and
a metal oxide, wherein the metal oxide is dispersed within the base material.
   (14)
   A recording device including the liquid ejection head according to above (13).

1. A piezoelectric actuator, comprising:
a piezoelectric element that deforms in response to an applied voltage,
wherein
the piezoelectric element comprises:
a piezoelectric ceramic body; and
an electrode configured to apply a voltage to the piezoelectric ceramic body,
wherein
the electrode comprises:
a base material containing a noble metal; and
a metal oxide,
wherein
the metal oxide is dispersed within the base material.

2. The piezoelectric actuator according to claim 1, wherein
an area ratio of the metal oxide dispersed within the base material is in a range of 15% to 30%.

3. The piezoelectric actuator according to claim 1, wherein
an area ratio of the metal oxide dispersed within the base material is in a range of 20% to 30%.

4. The piezoelectric actuator according to claim 1, wherein
the metal oxide is located at an interface between the base material and the piezoelectric ceramic body.

5. The piezoelectric actuator according to claim 4, wherein
the area ratio of the metal oxide dispersed within the base material to the metal oxide located at the interface between the base material and the piezoelectric ceramic body is in a range of 20% to 60%.

6. The piezoelectric actuator according to claim 4, wherein
the area ratio of the metal oxide dispersed within the base material to the metal oxide located at the interface between the base material and the piezoelectric ceramic body is in a range of 40% to 60%.

7. A piezoelectric actuator, comprising:
a piezoelectric element that deforms upon application of a voltage,
wherein
the piezoelectric element comprises:
a piezoelectric ceramic body; and
an electrode configured to apply a voltage to the piezoelectric ceramic body,
wherein
the electrode comprises:
a base material containing a noble metal; and
a metal oxide, wherein the metal oxide is exposed on the surface of the base material.

8. The piezoelectric actuator according to claim 7, wherein
the area ratio of the metal oxide exposed on the surface of the base material is in a range of 0.5% to 6%.

9. The piezoelectric actuator according to claim 7, wherein
the area ratio of the metal oxide exposed on the surface of the base material is in a range of 2% to 6%.

10. The piezoelectric actuator according to claim 1, wherein
the metal oxide comprises an oxide of a metal that is contained in the piezoelectric ceramic body.

11. The piezoelectric actuator according to claim 1, wherein
the metal oxide comprises a Pb oxide.

12. The piezoelectric actuator according to claim 1, wherein
the electrode is a surface electrode located on the surface of the piezoelectric ceramic body.

13. A liquid ejection head, comprising:
a nozzle configured to eject liquid droplets;
a pressurizing chamber connected to the nozzle; and
a piezoelectric element configured to deform in response to an applied voltage, thereby deforming the pressurizing chamber,
wherein
the piezoelectric element comprises:
a piezoelectric ceramic body; and
an electrode configured to apply a voltage to the piezoelectric ceramic body,
wherein
the electrode comprises:
a base material containing a noble metal; and
a metal oxide, wherein the metal oxide is dispersed within the base material.

14. A recording device comprising the liquid ejection head according to claim 13.

15. The piezoelectric actuator according to claim 7, wherein
the metal oxide comprises an oxide of a metal that is contained in the piezoelectric ceramic body.

16. The piezoelectric actuator according to claim 7, wherein
the metal oxide comprises a Pb oxide.

17. The piezoelectric actuator according to claim 7, wherein
the electrode is a surface electrode located on the surface of the piezoelectric ceramic body.
